(19) United States
(12) Patent Application Publication
(10) Pub. No.: US 2012/0241317 A1
(43) Pub. Date: Sep. 27, 2012

(54) Sputtering Target Comprising Oxide Phase Dispersed in Co or Co Alloy Phase, Magnetic Thin Film Made of Co or Co Alloy Phase and Oxide Phase, and Magnetic Recording Medium Using the Said Thin Film

(75) Inventors: Yuki Ikeda, Ibaraki (JP); Yuichiro Nakamura, Ibaraki (JP); Shin-ichi Ogino, Ibaraki (JP)

(73) Assignee: JX NIPPON MINING & METALS CORPORATION, Tokyo (JP)

(21) Appl. No.: 13/513,898

(22) PCT Filed: Oct. 13, 2010
(86) PCT No.: PCT/JP2010/067947

§ 371 Date: Jun. 5, 2012

(30) Foreign Application Priority Data
Dec. 11, 2009 (JP) 2009-281470

(51) Int. Cl. C23C 14/08; H01F 1/01; C23C 14/34

(52) U.S. Cl. 204/298.13; 252/62.51 C; 252/62.55

(57) ABSTRACT

A sputtering target comprising an oxide phase is dispersed in Co or a Co alloy phase, wherein the sputtering target is configured from a metal matrix phase containing Co, and a phase containing SiO₂ and having an oxide which forms particles and is dispersed in an amount of 6 to 14 mol % (hereinafter referred to as the “oxide phase”), the sputtering target contains, in addition to components configuring the metal matrix phase and the oxide phase, a Cr oxide scattered in or on a surface of the oxide phase in an amount of 0.3 mol % or more and less than 1.0 mol %, and an average area of the respective particles contained in the oxide phase is 2.0 μm² or less. The provided sputtering target comprising an oxide phase is dispersed in Co or a Co alloy phase can reduce arcing, obtain a stable discharge in a magnetron sputtering device, and reduce the amount of particles that is generated during high density sputtering.

### TECHNICAL FIELD

The present invention relates to a sputtering target comprising an oxide phase dispersed in Co or a Co alloy phase for use in the deposition of a magnetic thin film of a magnetic recording medium, particularly a granular magnetic recording film of a hard disk adopting the perpendicular magnetic recording system, and particularly relates to a sputtering target that can reduce arcing, obtain a stable discharge in a magnetron sputtering device, and reduce the amount of particles that is generated during high density sputtering. The present invention additionally relates to a magnetic thin film that is produced by sputtering the foregoing target, and a magnetic recording medium that uses the foregoing magnetic thin film.

### BACKGROUND OF ARTS

In the field of magnetic recording, technology of improving the magnetic property by refining and dispersing a nonmagnetic material in a magnetic thin film has been developed. As one such example, with a recording medium of a hard disk that adopts a perpendicular magnetic recording system, the various characteristics as a magnetic recording medium are improved by adopting a granular film which uses a nonmagnetic material to block, or weaken, the magnetic interaction between the magnetic particles in the magnetic recording film.

Co—Cr—Pt—SiO₂ is known as one of the optimal materials for the foregoing granular film, and this Co—Cr—Pt—SiO₂ granular film is generally prepared by sputtering a nonmagnetic material particle-dispersed magnetic material target in which SiO₂ as a nonmagnetic material is uniformly dispersed in a base metal of a ferromagnetic Co—Cr—Pt alloy having Co as its main component.

It is widely known that this kind of nonmagnetic material particle-dispersed magnetic material sputtering target is produced via the powder metallurgy process, since it is impossible to uniformly refine and disperse the nonmagnetic material particles in the magnetic alloy base metal via the melting method.

For example, proposed is a method of performing mechanical alloying to an alloy powder having an alloy phase prepared by the rapid solidification method and a powder configuring the ceramic phase, causing the powder configuring the ceramic phase to be uniformly dispersed in the alloy powder, and performing hot press thereto in order to obtain a sputtering target for use in a magnetic recording medium (Patent Document 1).

Moreover, without having to use the alloy powder prepared by the rapid solidification method, it is also possible to produce a nonmagnetic material particle-dispersed magnetic material sputtering target by preparing commercially available raw material powders for the respective components configuring the target, weighing these raw material powders to achieve the intended composition, mixing the raw material powders with a known method such as a ball mill or the like, and molding and sintering the mixed powder via hot press.

Moreover, it is generally known that, if a high density material can be obtained after the sintering process, the amount of problematic particles that is generated during sputtering will be low.

There are various types of sputtering devices, but a magnetron sputtering device is widely used in the deposition of the foregoing magnetic recording film in light of its high productivity.

With the sputtering method, a substrate as the positive electrode and a target as the negative electrode are caused to face each other, and a high voltage is applied between the substrate and the target in an inert gas atmosphere so as to generate an electric field.

Here, the inert gas is ionized and plasma made of electrons and positive ions is formed. When the positive ions in the plasma collide with the surface of the target (negative electrode), the atoms configuring the target are sputtered, and the sputtered atoms adhere to the opposing substrate surface and thereby form a film. As a result of this sequence of processes, the principle of the material configuring the target being deposited on the substrate is used.

The magnetron sputtering device is characterized in that a magnet is provided to the rear face side of the target, the magnetic flux (leakage magnetic flux) that leaks from the magnet to the target surface causes the electrons to engage in cycloidal motion near the target surface, and plasma is thereby generated efficiently.

In the case of a magnetic material target containing metals such as Co, Cr, and Pt and oxides such as SiO₂, since oxides such as SiO₂ have no conductivity, there is a problem in that the generation of particles will increase during sputtering if the area of the respective particles of the oxide phase exposed on the target surface is large. In order to resolve this problem, it is necessary to reduce the area of the respective particles of the oxide phase as much as possible.

Upon reviewing the conventional technology, Patent Document 2 describes inhibiting the grain growth of the oxide phase and uniformly dispersing such oxide phase by including Cr in the oxide phase, and thereby obtaining a high density target. With Patent Document 2, the key point in inhibiting of the grain growth of the oxide phase is using electric current sintering, in addition to adding chromium.

Nevertheless, the chromic oxide content is high at 1.2 to 12.0 mol %, and the addition of this kind of large amount is problematic since it will considerably change the characteristics as a nonmagnetic material particle-dispersed magnetic thin film, and as a magnetic recording medium that uses such a nonmagnetic material particle-dispersed magnetic thin film. Moreover, even though a silicon oxide raw material powder having an average grain size of 0.5 μm is being used, the grain size of the obtained oxide phase is roughly 2 to 2.5 μm, and there is a problem in that it cannot be said that the grain size is sufficiently refined.

Moreover, Patent Document 3 proposes inhibiting the generation of particles by adding a Cr oxide to the oxide phase. Moreover, Patent Document 3 cites Patent Document 4, Patent Document 5 and the like and describes that the generation of particles cannot be inhibited only with the refinement of the silica phase, and further describes that this problem cannot be resolved if the “adhesion between the alloy phase and the silica phase is inferior”. Since Patent Document 3 deems the cited silica phase of 10 μm or less as being “fine” and sets the grain size of the raw material powder SiO₂ to 20 μm or less and specifically uses 3 μm in the Examples, Patent Document 3 suggests that an oxide phase is a structure having a grain size of the foregoing level or larger.

Paragraph [0010] of Patent Document 3 describes performing hot press at a temperature of 1200° C. for 3 hours. When hot press is performed at this kind of high temperature and for a long period, coarsening of SiO₂ will occur as a matter of course and, therefore, it is obvious that the sufficient refinement of SiO₂ cannot be achieved. Patent Document 3 describes adding 0.01 to 0.5 mass % of Cr in order to reduce the generation of particles, and it can be determined that the oxide phase is coarse.
[Patent Document 1] Japanese Unexamined Patent Application Publication No. H10-88333
[Patent Document 2] Japanese Unexamined Patent Application Publication No. 2009-215617
[Patent Document 3] Japanese Unexamined Patent Application Publication No. 2007-31808
[Patent Document 4] Japanese Unexamined Patent Application Publication No. 2001-236643
[Patent Document 5] Japanese Unexamined Patent Application Publication No. 2004-339586

### SUMMARY OF THE INVENTION

### Problems to be Solved by the Invention

Generally speaking, when a nonmagnetic material particle-dispersed magnetic material sputtering target is sputtered using the foregoing magnetron sputtering device, arcing occurs based on the oxide particles, and there is a major problem in that the discharge becomes unstable.

In order to resolve this problem, it is effective to uniformly disperse SiO₂.

An object of this invention is to provide a nonmagnetic material particle-dispersed magnetic material sputtering target capable of reducing arcing, obtaining a stable discharge in a magnetron sputtering device, and reducing the amount of particles that is generated during high density sputtering.

### Means for Solving the Problems

In order to achieve the foregoing object, as a result of conducting intense study, the present inventors and others discovered that it is possible to obtain a target capable of reducing arcing by adjusting the constitution of the target, and further discovered that this target can realize sufficiently high density and reduce the amount of particles that is generated during sputtering.

Based on the foregoing discovery, the present invention provides the following invention.

1) A sputtering target comprising an oxide phase dispersed in Co or a Co alloy phase, wherein the sputtering target is configured from a metal matrix phase containing Co, and a phase containing SiO₂ and having an oxide which forms particles and is dispersed in an amount of 6 to 14 mol % (hereinafter referred to as the “oxide phase”), the sputtering target contains, in addition to components configuring the metal matrix phase and the oxide phase, a Cr oxide scattered in or on a surface of the oxide phase in an amount of 0.3 mol % or more and less than 1.0 mol %, and an average area of the respective particles contained in the oxide phase is 2.0 μm² or less.

A more preferable average area of the respective particles of the oxide phase is 1.5 μm² or less.

2) The sputtering target comprising an oxide phase dispersed in Co or a Co alloy phase according to 1) above, wherein the metal matrix phase is a Co metal by itself, or a Co-base alloy containing 6 to 40 mol % of Cr and the remainder being Co, or a Co-base alloy containing 6 to 40 mol % of Cr, 8 to 20 mol % of Pt and the remainder being Co.

These are typical Co-based nonmagnetic material particle-dispersed magnetic materials, and the present invention can be suitably applied thereto.

3) The sputtering target comprising an oxide phase dispersed in Co or a Co alloy phase according to 1) or 2) above, wherein the specific resistance is 3.5×10¹⁶ Ω·cm or less.
4) The sputtering target comprising an oxide phase dispersed in Co or a Co alloy phase according to any one of 1) to 3) above, wherein the relative density is 98% or more.

The present invention is characterized in that the particles of the oxide phase can be refined, and the relative density can be improved.

5) A nonmagnetic material particle-dispersed magnetic thin film, comprising a metal matrix phase containing Co, an oxide phase containing 6 to 14 mol % of SiO₂, and a Cr oxide in an amount of 0.3 mol % or more and less than 1.0 mol %.

The nonmagnetic material particle-dispersed magnetic thin film of the present invention is obtained by performing deposition using the foregoing sputtering target, and, since the component composition of the target is reflected in the component composition of the thin film formed via sputtering, it comprises the same component composition.

6) The nonmagnetic material particle-dispersed magnetic thin film according to 5) above, wherein the metal matrix phase is a Co metal by itself, or a Co-base alloy containing 6 to 40 mol % of Cr and the remainder being Co, or a Co-base alloy containing 6 to 40 mol % of Cr, 8 to 20 mol % of Pt and the remainder being Co.
7) The nonmagnetic material particle-dispersed magnetic thin film according to 5) or 6) above, wherein the specific resistance is 3.5×10¹⁶ Ω·cm or less.
8) A magnetic recording medium which uses the nonmagnetic material particle-dispersed magnetic thin film according to any one of 5) to 7) above.

The sputtering target comprising an oxide phase dispersed in Co or a Co alloy phase of the present invention preferably has, as described above, a relative density of 98% or more. As a result of the relative density being 98% or more, the adhesion between the alloy and the nonmagnetic material particles will increase. Thus, the shedding of nonmagnetic material particles during sputtering can be inhibited, and the amount of particles that is generated can be reduced.

The term “relative density” as used herein refers to a value that is obtained by dividing the measured density of the target by the calculated density. The term “calculated density” refers to the density upon assuming that the constituents of the target coexist without mutually dispersing or reacting, and is calculated by the following formula.

Formula:

Calculated density=Σ(molecular weight of constituents×molar ratio of constituents)/Σ(molecular weight of constituents×molar ratio of constituents /literature data density of constituents)

Here, “Σ” refers to the sum of all constituents of the target.

### Effect of the Invention

It is possible to obtain a target in which fine SiO₂, which is a nonmagnetic material, is uniformly dispersed in a base metal of Co or an alloy having Co as its main component. In other words, it is possible to provide a sputtering target comprising an oxide phase dispersed in Co or a Co alloy phase which contains, in addition to components configuring the metal matrix phase and the oxide phase, a Cr oxide scattered in or on a surface of the oxide phase in an amount of 0.3 mol % or more and less than 1.0 mol %, and in which the average area of the respective particles contained in the oxide phase is 2.0 μm² or less.

Thus, it is possible to considerably reduce the amount of generated particles through the refinement and high densification of the SiO₂ oxide particles. In addition, there are advantages in that a stable discharge can be obtained since the target will yield minimal arcing, and a magnetic thin film can be produced with a low cost.

### BRIEF DESCRIPTION OF THE DRAWINGS

FIG. 1 is a texture image upon observing the target face of Example 1 using a scanning electron microscope (SEM).

FIG. 2 is a texture image upon observing the target face of Comparative Example 1 using a scanning electron microscope (SEM).

FIG. 3 is a texture image upon observing the target face of Example 2 using a scanning electron microscope (SEM).

FIG. 4 is a texture image upon observing the target face of Comparative Example 2 using a scanning electron microscope (SEM).

### DETAILED DESCRIPTION OF THE INVENTION

The sputtering target comprising an oxide phase dispersed in Co or a Co alloy phase of the present invention is a sputtering target configured from a magnetic metal matrix phase containing Co, and a phase containing SiO₂ and having an oxide which forms particles and is dispersed in an amount of 6 to 14 mol % (hereinafter referred to as the “oxide phase”).

The sputtering target contains, in addition to components configuring the metal matrix phase and the oxide phase, a Cr oxide scattered in or on a surface of the oxide phase in an amount of 0.3 mol % or more and less than 1.0 mol %, and an average area of the respective particles contained in the oxide phase is 2.0 μm² or less.

The present invention is applied to Co or a Co-base alloy as noted above. As a typical Co-based nonmagnetic material particle-dispersed magnetic material, a Co-base alloy containing 6 to 40 mol % of Cr and the remainder being Co, or a Co-base alloy containing 6 to 40 mol % of Cr, 8 to 20 mol % of Pt and the remainder being Co may be used. The present invention can be suitably applied to these materials.

Generally speaking, even if a fine SiO₂ sintering raw material is simply added and sintering is performed, it was usually the case that the material would flocculate and become coarse. In particular, a refined and dispersed sputtering target was desired via sintering at roughly 1200° C., but with the conventional production method (mixing method, sintering conditions), the average area per SiO₂ grain of the sintered target was 3 μm² or more (assuming this to be a circle, this will be a grain size of 2 μm or more). In the foregoing case, the material can be refined by lowering the sintering temperature or shortening the sintering time, but even still the limit is roughly 2.5 μm². Here, contrarily, the sintering will be insufficient and cause insufficient density (insufficient sintering), and there is a problem in that abnormal discharge (arcing) or the generation of particles will increase during sputtering.

The conventional production methods are an extension of the foregoing method, and, even upon adding a chromic oxide, sintering is performed at a high temperature and for a long period in order to increase the density. Consequently, the average area per SiO₂ grain becomes 3 μm² or higher. This cannot necessarily be referred to as the refinement of SiO₂ grains, and it can be said that the generation of a certain level of abnormal discharge (arcing) and particles during sputtering was being tolerated. Although attempts have been made such as in Patent Document 2 and Patent Document 3 that aim to reduce particles, it was not possible to sufficiently refine the oxide phase without affecting the characteristics of the magnetic material.

The present invention resolves the foregoing problems. In other words, as its solution, the present invention proposes including fine particles of a high melting point oxide, which has a considerably slower dispersion rate at the same temperature, on the surface of the oxide containing SiO₂ or in the gaps between the oxide particles in the sintering process so as to inhibit the flocculation of the oxides containing SiO₂.

Here, the phrase “oxide phase containing SiO₂” refers to an oxide phase where the oxide is only SiO₂, and an oxide phase where SiO₂ and other oxides are combined. As the oxides, there are cases where oxides other than SiO₂; for example, TiO₂ having similar characteristics, are contained, and this shall refer to cases where the existence of oxides is strongly affected by SiO₂.

Accordingly, the oxide containing SiO₂ is sintered while maintaining a particle size that is basically the same as the raw material powder and, as a result, the area of the respective particles of the oxide phase can be reduced, and limited to 2.0 μm² or less depending on the sintering conditions.

Note that, as described above, even if a raw material powder of an oxide containing SiO₂ having a small grain size is simply used, the surface energy will increase as the particle size becomes smaller. Thus, the raw material powder tends to flocculate, and it is not possible to cause the grain size after sintering to be the grain size of the raw material powder.

As a means for realizing the above, a high melting point oxide of a Cr oxide is added in an amount of 0.3 mol % or more and less than 1.0 mol %. Moreover, the sintering conditions are moderately controlled so as to inhibit the growth of the oxide particles containing SiO₂. If the additive amount of the foregoing Cr oxide is less than 0.3 mol %, the SiO₂ particles will flocculate, and it is not possible to achieve 2.0 μm² or less as the average particle area of SiO₂. Thus, it is not possible to reduce the generation of particles.

Meanwhile, if the additive amount of the Cr oxide is 1.0 mol % or more, the magnetic properties will change and it becomes difficult to prepare a magnetic film having predetermined characteristics. Moreover, in order to increase the density by adding 1.0 mol % or more of the Cr oxide, it is necessary to adopt sintering conditions of a higher temperature and a longer period. However, since the dispersion, flocculation and grain growth of SiO₂ in the sintering process will be accelerated, it becomes impossible to inhibit the same.

SiO₂ is an insulator, but by adding the Cr oxide, the conductivity as the sintered compact can be reduced to a specific resistance of 3.5×10¹⁶ Ωcm or less.

Even in cases where the Cr oxide not added intentionally, if the matrix phase contains Cr, there are cases where oxidation will occur during sintering and a Cr oxide (Cr₂O₃) is formed in an amount of roughly 0.1 to 0.2 mol %.

In this respect, it is considered that a conventionally produced oxide-dispersed Co alloy sputtering target naturally contained Cr oxide in an amount of roughly 0.1 to 0.2 mol %. In the foregoing case, the SiO₂ grains are coarse, and no effect can be yielded regarding the specific resistance or permittivity of the oxide phase. This is an effect that can be yielded considerably when the Cr oxide content is 0.3 mol % or more.

Upon producing the sputtering target comprising an oxide phase dispersed in Co or a Co alloy phase of the present invention, as the magnetic metal, for example, a Co powder having an average grain size of 1 μm, a Cr powder having an average grain size of 2 μm, a Pt powder having an average grain size of 2 μm, and a SiO₂ powder having an average grain size of 1 μm are prepared, and these powders are mixed with a Cr₂O₃ powder using a mixer.

When the Cr₂O₃ powder is added within the foregoing range, the average grain size of the Cr₂O₃ powder is desirably 0.6 μm or less. Moreover, when SiO₂ is similarly added within the foregoing range, the average grain size of the SiO₂ raw material powder is desirably 1 μm or less.

By molding and sintering the powder obtained as described above using a vacuum hot press device, and cutting it into an intended shape, it is possible to produce the sputtering target comprising an oxide phase dispersed in Co or a Co alloy phase of the present invention.

The molding and sintering processes are not limited to the hot press method, and a plasma discharge sintering method or a hot isostatic sintering method may also be used. The holding temperature in the sintering process is preferably set to the lowest temperature within the temperature range in which the target can be sufficiently densified. Although this will depend on the composition of the target, in many cases this will be within a temperature range of 900 to 1200° C.

The average area per SiO₂ particle can be obtained by performing image processing to a microscopic image. The density is most preferably measured via the Archimedian method, but it may also be measured based on the dimension measurement and weight measurement. The relative density can be calculated based on the absolute density measured as described above, and the calculated density obtained by calculating that the respective molecules coexist in the composition ratio.

The addition of the Cr oxide can be achieved, for example, by uniformly mixing Cr₂O₃ to the respective elemental powders of Co—Cr—Pt—SiO₂ or the like, or the mixed powder configuring the alloy powder. Moreover, by moderately subjecting the Cr powder, the Co-Cr powder or the Co—Cr—Pt powder to natural oxidation in the pulverize or mixing process, it is also possible to add the Cr oxide by causing a part of Cr that existed as metal to become the Cr oxide.

### Examples

The present invention is now explained based on the Examples and the Comparative Examples. Note that these Examples are illustrative only, and the present invention shall not be limited to these Examples in any way. In other words, this invention is limited only by the scope of claims indicated below, and covers the various modes other than the Examples contained in the present invention.

### Example 1

As the raw material powder in Example 1, a Co powder with an average grain size of 1 μm, a Cr powder with an average grain size of 2 μm, a SiO₂ powder with an average grain size of 1 μm, and a Cr₂O₃ powder with an average grain size of 0.6 μm were prepared.

These powders were respectively weighed at a weight ratio of Co powder 79.73 wt %, Cr powder 10.60 wt %, SiO₂ powder 7.73 wt %, and Cr₂O₃ powder 1.94 wt % so as to achieve a target composition of 12.00 Cr, 7.58 SiO₂, 0.75 Cr₂O₃, and remainder Co (mol %).

Subsequently, the Co powder, the Cr powder, the SiO₂ powder, and the Cr₂O₃ powder were enclosed in a ball mill pot having a volume of 10 liters together with zirconia balls as the pulverizing medium, and rotated and mixed for 20 hours. The obtained mixed powder was filled in a carbon mold, and hot pressed in a vacuum atmosphere under the following conditions; namely, temperature of 1150° C., holding time of 90 minutes, and applied pressure of 30 MPa, to obtain a sintered compact. The obtained sintered compact was further cut with a lathe to obtain a disk-shaped target having a diameter of 180 mm and a thickness of 7 mm.

In Example 1, a high density target in which the relative density exceeded 99% was obtained. The texture image upon observing the polished surface of the target of Example 1 using a scanning electron microscope (SEM) is shown in FIG. 1. As shown, what is extremely unique in foregoing Example 1 is that the SiO₂ particles are finely dispersed in the matrix alloy phase. In FIG. 1, the finely dispersed objects are the SiO₂ particles. Moreover, the average area of the respective particles of the oxide phase was 1.6 μm². The average area of the respective particles of the oxide phase and the analysis of the components configuring the target are shown in Table 1.

TABLE 1

| | average area of respective | | | | | | | |
|---|---|---|---|---|---|---|---|---|
| | particle of the oxide phase | analysis of components (mol. %) | | | | | | |
| | (μm²) | Co | Cr | Pt | Ru | Ta₂O₅ | SiO₂ | Cr₂O₃ |
| Example 1 | 1.6 | balance | 11.69 | — | — | — | 7.33 | 0.92 |
| Comparative | 2.4 | balance | 11.75 | — | — | — | 7.25 | 0.26 |
| Example 1 | | | | | | | | |
| Example 2 | 2.0 | balance | 15.84 | 17.92 | 4.12 | 0.96 | 6.09 | 0.89 |
| Comparative | 2.7 | balance | 15.73 | 17.96 | 3.87 | 0.95 | 6.11 | 0.22 |
| Example 2 | | | | | | | | |

### Comparative Example 1

As the raw material powder in Comparative Example 1, as with Example 1, a Co powder with an average grain size of 1 μm, a Cr powder with an average grain size of 2 μm, and a SiO₂ powder with an average grain size of 1 μm were prepared.

These powders were respectively weighed at a weight ratio of Co powder 81.45 wt %, Cr powder 10.72 wt %, and SiO₂ powder 7.83 wt % so as to achieve a target composition of 12.00 Cr, 7.58 SiO₂, and remainder Co (mol %). The difference with Example 1 is that the Cr₂O₃ powder is not added.

After mixing these powders as with Example 1, the obtain mixed powder was filled in a carbon mold, and hot pressed in a vacuum atmosphere under the following conditions; namely, temperature of 1150° C., holding time of 90 minutes, and applied pressure of 30 MPa, to obtain a sintered compact. The obtained sintered compact was further cut with a lathe to obtain a disk-shaped target having a diameter of 180 mm and a thickness of 7 mm.

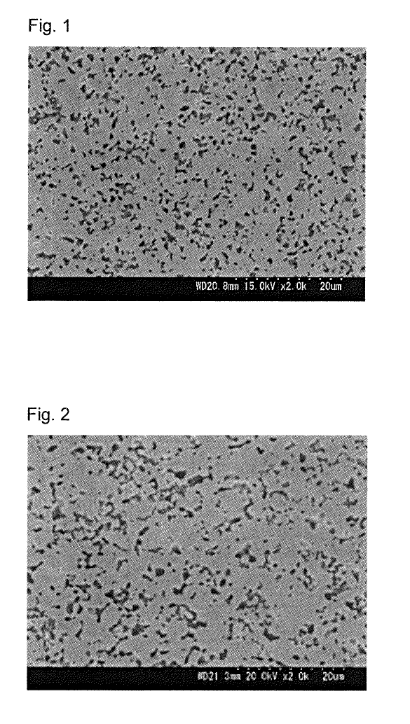

In Comparative Example 1, a high density target in which the relative density exceeded 99% was obtained as with Example 1. The texture image upon observing the polished surface of the target of Comparative Example 1 using a scanning electron microscope (SEM) is shown in FIG. 2. As shown, in Comparative Example 1, the SiO₂ particles in the matrix alloy phase are coarse in comparison to Example 1. And the average area of the respective particles of the oxide phase was 2.4 μm². The average area of the respective particles of the oxide phase and the analysis of the components configuring the target are shown in Table 1.

### Example 2

As the raw material powder in Example 2, a Co powder with an average grain size of 1 μm, a Cr powder with an average grain size of 2 μm, a Pt powder with an average grain size of 2 μm, a Ru powder with an average grain size of 2 μm, a Ta₂O₅ powder with an average grain size of 2 μm, a SiO₂ powder with an average grain size of 1 μm, and a Cr₂O₃ powder with an average grain size of 0.6 μm were prepared.

These powders were respectively weighed to achieve a target composition of 16 Cr, 18 Pt, 4 Ru, 1 Ta₂O₅, 6 SiO₂, 0.75 Cr₂O₃, and remainder Co (mol %).

Subsequently, the Co powder, the Cr powder, the Pt powder, the Ru powder, the SiO₂ powder, the Ta₂O₅ powder, and the Cr₂O₃ powder were enclosed in a ball mill pot having a volume of 10 liters together with zirconia balls as the pulverizing medium, and rotated and mixed for 20 hours.

The obtained mixed powder was filled in a carbon mold, and hot pressed in a vacuum atmosphere under the following conditions; namely, temperature of 1150° C., holding time of 2 hours, and applied pressure of 30 MPa, to obtain a sintered compact.

The obtained sintered compact was further cut with a lathe to obtain a disk-shaped target having a diameter of 180.0 mm and a thickness of 7.0 mm.

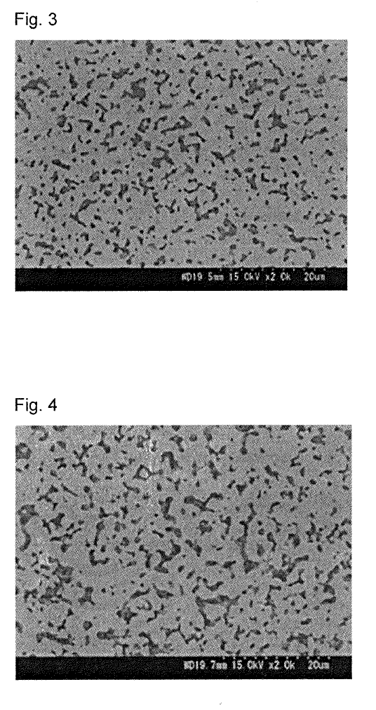

In Example 2, a high density target in which the relative density exceeded 99% was obtained. The texture image upon observing the polished surface of the target of Example 2 using a scanning electron microscope (SEM) is shown in FIG. 3. As shown, what is extremely unique in foregoing Example 2 is that the Ta₂O₅ particles and SiO₂ particles are finely dispersed in the matrix alloy phase. In FIG. 3, the finely dispersed objects are the Ta₂O₅ particles and SiO₂ particles. Moreover, the average area of the respective particles of the oxide phase was 2.0 μm². The average area of the respective particles of the oxide phase and the analysis of the components configuring the target are shown in Table 1.

### Comparative Example 2

As the raw material powder in Comparative Example 2, as with Example 2, a Co powder with an average grain size of 1 μm, a Cr powder with an average grain size of 2 μm, a Pt powder with an average grain size of 2 μm, a Ru powder with an average grain size of 2 μm, a Ta₂O₅ powder with an average grain size of 2 μm, and a SiO₂ powder with an average grain size of 1 μm were prepared. These powders were respectively weighed to achieve a target composition of 16 Cr, 18 Pt, 4 Ru, 1 Ta₂O₅, 6 SiO₂, and remainder Co (mol %). The difference with Example 2 is that the Cr₂O₃ powder is not added.

After mixing these powders as with Example 2, the obtain mixed powder was filled in a carbon mold, and hot pressed in a vacuum atmosphere under the following conditions; namely, temperature of 1150° C., holding time of 90 minutes, and applied pressure of 30 MPa, to obtain a sintered compact. The obtained sintered compact was further cut with a lathe to obtain a disk-shaped target having a diameter of 180 mm and a thickness of 7 mm.

In Comparative Example 2, a high density target in which the relative density exceeded 99% was obtained as with Example 2. The texture image upon observing the polished surface of the target of Comparative Example 2 using a scanning electron microscope (SEM) is shown in FIG. 4. As shown, in Comparative Example 2, the Ta₂O₅ particles and SiO₂ particles in the matrix alloy phase are coarse in comparison to Example 2. Moreover, the average area of the respective particles of the oxide phase was 2.7 μm². The average area of the respective particles of the oxide phase and the analysis of the components configuring the target are shown in Table 1.

Note that, in the foregoing Examples and Comparative Examples, an example of a typical Co-base alloy was illustrated, but since the present invention is primarily used for examining the influence when a Cr oxide is contained in a case where the SiO₂ oxide phase exists in a metal matrix phase containing Co, so as long as the metal matrix phase is Co or a Co-base alloy, a similar tendency is yielded, and it should be easy to understand that the present invention can be applied to a metal matrix phase which is a Co metal by itself, or other Co-base alloys.

Moreover, the foregoing Examples and Comparative Examples explained a case where the SiO₂ oxide phase exists in the metal matrix phase, but even in cases where SiO₂ contains TiO₂, it should be easy to understand that similar results as SiO₂ can be obtained since TiO₂ possesses characteristics and functions that are basically the same as SiO₂. The present invention covers all of the foregoing aspects.

### INDUSTRIAL APPLICABILITY

The present invention is a sputtering target comprising an oxide phase is dispersed in Co or a Co alloy phase, wherein the sputtering target is configured from a metal matrix phase containing Co, and a phase containing SiO₂ and having an oxide which forms particles and is dispersed in an amount of 6 to 14 mol % (hereinafter referred to as the “oxide phase”), the sputtering target contains, in addition to components configuring the metal matrix phase and the oxide phase, a Cr oxide scattered in or on a surface of the oxide phase in an amount of 0.3 mol % or more and less than 1.0 mol %, and an average area of the respective particles contained in the oxide phase is 2.0 μm² or less. Thus, it is possible to considerably reduce the amount of generated particles through the refinement and high densification of the oxide particles containing SiO₂.

Accordingly, it is possible to realize stable and highly productive sputtering of a sputtering target comprising an oxide phase dispersed in Co or a Co alloy phase by using a magnetron sputtering device. In addition, since the target yields superior effects of being able to reduce arcing, efficiently promote ionization of inert gas when used in a magnetron sputtering device, obtain a stable discharge, and thereby enable the production of a magnetic thin film at a low cost, it is useful as a sputtering target comprising an oxide phase dispersed in Co or a Co alloy phase for use in the deposition of a magnetic thin film of a magnetic recording medium, in particular a granular magnetic recording film of a hard disk adopting the perpendicular magnetic recording system.

1. A sputtering target comprising an oxide phase dispersed in Co or a Co alloy phase, wherein the sputtering target is configured from a metal matrix phase containing Co, and an oxide phase containing SiO₂ and having an oxide which forms particles and is dispersed in an amount of 6 to 14 mol %, the sputtering target contains, in addition to components configuring the metal matrix phase and the oxide phase, a Cr oxide scattered in or on a surface of the oxide phase in an amount of 0.3 mol % or more and less than 1.0 mol %, and an average area of the respective particles contained in the oxide phase is 2.0 μm² or less.

2. The sputtering target comprising an oxide phase dispersed in Co or a Co alloy phase according to claim 1, wherein the metal matrix phase is a Co metal by itself, or a Co-base alloy containing 6 to 40 mol % of Cr and the remainder being Co, or a Co-base alloy containing 6 to 40 mol % of Cr, 8 to 20 mol % of Pt and the remainder being Co.

3. The sputtering target comprising an oxide phase dispersed in Co or a Co alloy phase according to claim 2, wherein the specific resistance is 3.5×10¹⁶ Ω·cm or less.

4. The sputtering target comprising an oxide phase dispersed in Co or a Co alloy phase according to claim 3, wherein the relative density is 98% or more.

5. A nonmagnetic material particle-dispersed magnetic thin film formed by sputtering the sputtering target according to claim 1, comprising a metal matrix phase containing Co, an oxide phase containing 6 to 14 mol % of SiO₂, and a Cr oxide in an amount of 0.3 mol % or more and less than 1.0 mol %, wherein the specific resistance of the thin film is 3.5×10¹⁶ Ω·cm or less.

6. The nonmagnetic material particle-dispersed magnetic thin film according to claim 5, wherein the metal matrix phase is a Co metal by itself, or a Co-base alloy containing 6 to 40 mol % of Cr and the remainder being Co, or a Co-base alloy containing 6 to 40 mol % of Cr, 8 to 20 mol % of Pt and the remainder being Co.

7. (canceled)

8. A magnetic recording medium, comprising the nonmagnetic material particle-dispersed magnetic thin film according to claim 6.

9. The sputtering target according to claim 1, wherein the specific resistance of the sputtering target is 3.5×10¹⁶ Ω·cm or less.

10. The sputtering target according to claim 1, wherein the relative density of the sputtering target is 98% or more.
